(19) United States
(12) Patent Application Publication
(10) Pub. No.: US 2022/0115231 A1
(43) Pub. Date: Apr. 14, 2022

(54) WRAP-AROUND LABEL FOR SSD

(71) Applicant: Intel Corporation, Santa Clara, CA (US)

(72) Inventors: Cory Runyan, Folsom, CA (US); Cody Malnor, Bellevue, WA (US)

(73) Assignee: Intel Corporation, Santa Clara, CA (US)

(21) Appl. No.: 17/559,493

(22) Filed: Dec. 22, 2021

(51) Int. Cl. H01L 21/02

(52) U.S. Cl. CPC H01L 21/02362

(57) ABSTRACT

Systems, apparatuses, and methods may provide for technology for affixing a thermal label to a solid state drive. A printed circuit board of a solid state drive includes a top surface positioned opposite from a back surface. The printed circuit board further include one or more memory chips disposed on the top surface. A thermal label is affixed to the one or more memory chips disposed on the top surface of the printed circuit board and to the back surface of the printed circuit board.

### TECHNICAL FIELD

Embodiments generally relate to solid state drives. More particularly, embodiments relate to technology for affixing a thermal label to a solid state drive.

### BACKGROUND

A solid state drive (SSD) is a data storage device that uses integrated circuit assemblies as memory to store data persistently. SSDs have no moving mechanical memory components, and this distinguishes SSDs from traditional electromechanical magnetic drives, such as magnetic hard disk drives (HDDs), which contain spinning disks and movable read/write heads. Compared to HDDs, SSDs are typically more resistant to physical shock, run silently, have lower access time, and less latency.

Many types of SSDs use NAND-based flash memory which comprises an electronic (solid-state) non-volatile computer storage medium that can be electrically erased and reprogrammed. SSDs may include a printed circuit board (PCB) with a controller chip and a plurality of memory chips positioned thereon, with the SSD having an industry standard form factor, including, but not limited to, 2.5 inch and 3.5 inch form factors.

### BRIEF DESCRIPTION OF THE DRAWINGS

The various advantages of the embodiments will become apparent to one skilled in the art by reading the following specification and appended claims, and by referencing the following drawings, in which:

FIG. 1 is a front of an example of a memory device according to an embodiment;

FIG. 2 illustrates an example front view of an edge of a memory device based on the detail view A of FIG. 1 according to an embodiment;

FIG. 3 illustrates an example front view of another edge of a memory device according to an embodiment;

FIG. 4 illustrate an exploded diagram of an example thermal label according to an embodiment;

FIG. 5 illustrates a perspective diagram of another example memory device according to an embodiment;

FIG. 6 is a flowchart of an example method of forming a memory device according to an embodiment;

FIG. 7 is a block diagram of an example of a performance-enhanced computing system according to an embodiment.

### DESCRIPTION OF EMBODIMENTS

As described above, SSDs may have an industry standard form factor. As SSD form factors become smaller and smaller, undesirable heat may be generated by the SSD. For example, some Original Equipment Manufacturers (OEMs) are moving from the M.2 2280 form factor to the M. 2230 form factor. The M.2 2230 form factor is much smaller with higher thermal density. This results in the M.2 2230 form factor SSD heating up faster. When the SSD components reach critical temperatures, the SSDs typically throttle performance to cool off the drive. Accordingly, the M.2 2230 form factor SSD will typically throttle sooner than larger form factors, resulting in lower throughput performance.

As will be described in greater detail below, systems, apparatuses, and methods are described that may provide for technology for affixing a thermal label to a solid state drive. A printed circuit board of a solid state drive includes a top surface positioned opposite from a back surface. The printed circuit board further include one or more memory chips disposed on the top surface. A thermal label is affixed to the one or more memory chips disposed on the top surface of the printed circuit board and to the back surface of the printed circuit board.

For example, such a thermal label includes an embedded graphite layer in some implementations. The thermal label is applied the SSD where it is applied to the top of the SSD and wrapped around one edge of the SSD and adhered to the back of the SSD.

Such a graphite embedded thermal label moves the heat away from the hot components on the top of the SSD to other areas of the SSD (e.g., to the back of the SSD) that are typically cooler. This typically increases the time for the drive components to reach temperatures that trigger throttling, which advantageously results in improved throughput performance.

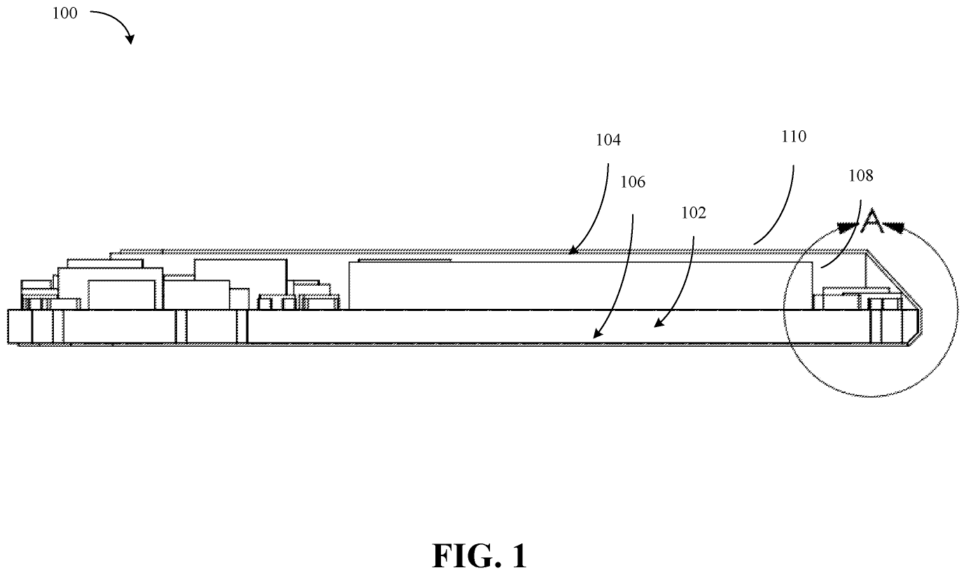

FIG. 1 is a block diagram of an example of a memory device 100 according to an embodiment. As illustrated, the memory device 100 is implemented as a solid state drive in some examples.

The memory device 100 includes a printed circuit board 102. The printed circuit board 102 includes a top surface 104 positioned opposite from a back surface 106. In some implementations, the printed circuit board 102 further includes one or more memory chips 108 disposed on the top surface 104.

The memory device 100 includes a thermal label 110 affixed to the one or more memory chips 108 disposed on the top surface 104 of the printed circuit board 102 and affixed to the back surface 106 of the printed circuit board 102.

In some implementations, in order to accommodate the added thickness of the thermal label 110 wrapping the top and back of the memory device 100, the printed circuit board 102 is manufactured to have a smaller side thickness. For example, the printed circuit board 102 is designed to have a side thickness that is shorter than is typical for the typical form factor dimensions (e.g., 200 μm or the like, depending on the thickness of the thermal label 110). Accordingly, in some implementations, the printed circuit board 102 is sized to accommodate application of the thermal layer 110 to the top surface 104 and the back surface 106 of the printed circuit board 102 while maintaining an overall side thickness of the memory device 100 consistent with a given form factor (e.g., the M.2 2230 form factor dimensions, or the like). Such a design advantageously allows the application of the thermal label 110 without exceeding the typical form factor dimensions (e.g., the M.2 2230 form factor dimensions, or the like).

In some implementations, the solid state drive includes a form factor that does not exceed thirty millimeters. In some examples, the solid state drive includes a housing including a plurality of sides surrounding an interior region where the printed circuit board is located within the interior region of the housing.

The memory device 100 may include non-volatile memory and/or volatile memory. For example, in some implementations, the solid state drive utilizes a multi-deck or multi-layer memory architecture, such as a three-dimensional crosspoint solid state drive, although other types of memory may be utilized.

Examples of multi-deck or multi-layer memory architectures include multi-deck crosspoint memory and 3D NAND memory. Different memory technologies have adopted different terminology. For example, a deck in a crosspoint memory device typically refers to a layer of memory cell stacks that can be individually addressed. In contrast, a 3D NAND memory device is typically said to include a NAND array that includes many layers, as opposed to decks. In 3D NAND, a deck may refer to a subset of layers of memory cells (e.g., two decks of X-layers to effectively provide a 2×-layer NAND device). The term “deck” will be used throughout this disclosure to describe a layer, a tier, or a similar portion of a three-dimensional memory.

Non-volatile memory is a storage medium that does not require power to maintain the state of data stored by the medium. In one embodiment, the memory structure is a block addressable storage device, such as those based on NAND or NOR technologies. A storage device may also include future generation nonvolatile devices, such as a three-dimensional (3D) crosspoint memory device, or other byte addressable write-in-place nonvolatile memory devices. In one embodiment, the storage device may be or may include memory devices that use silicon-oxide-nitride-oxide-silicon (SONOS) memory, electrically erasable programmable read-only memory (EEPROM), chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thiristor based memory device, or a combination of any of the above, or other memory. The term “storage device” may refer to the die itself and/or to a packaged memory product. In some embodiments, 3D crosspoint memory may comprise a transistor-less stackable cross point architecture in which memory cells sit at the intersection of word lines and bit lines and are individually addressable and in which bit storage is based on a change in bulk resistance. In particular embodiments, a memory module with non-volatile memory may comply with one or more standards promulgated by the Joint Electron Device Engineering Council (JEDEC), such as JESD235, JESD218, JESD219, JESD220-1, JESD223B, JESD223-1, or other suitable standard (the JEDEC standards cited herein are available at jedec.org).

Volatile memory is a storage medium that requires power to maintain the state of data stored by the medium. Examples of volatile memory may include various types of random access memory (RAM), such as dynamic random access memory (DRAM) or static random access memory (SRAM). One particular type of DRAM that may be used in a memory module is synchronous dynamic random access memory (SDRAM). In particular embodiments, DRAM of the memory modules complies with a standard promulgated by JEDEC, such as JESD79F for Double Data Rate (DDR) SDRAM, JESD79-2F for DDR2 SDRAM, JESD79-3F for DDR3 SDRAM, or JESD79-4A for DDR4 SDRAM (these standards are available at jedec.org). Such standards (and similar standards) may be referred to as DDR-based standards and communication interfaces of the storage devices that implement such standards may be referred to as DDR-based interfaces.

As will be described in greater detail below, systems, apparatuses and methods of some implementations herein provide for technology that provides the capability for affixing a thermal label to a solid state drive.

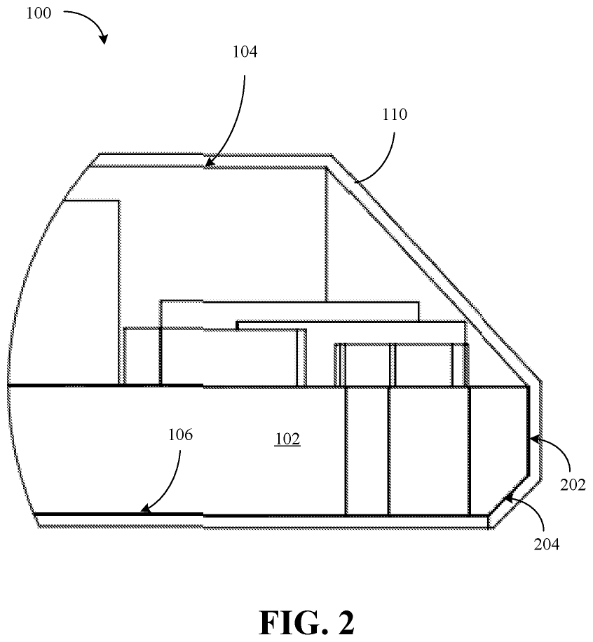

FIG. 2 illustrates an example front view of an edge of a memory device based on the detail view A of FIG. 1 according to an embodiment. As illustrated, the printed circuit board 102 further includes a side surface 202 extending perpendicular to the top surface 104 and the back surface 106. In particular, the printed circuit board 102 further includes a transitional edge 204 extending from the side surface 202 to the back surface 106.

In some examples, the transitional edge 204 is a chamfered edge. As used herein, the term “chamfered edge” refers to a corner having an edge with a 45 degree angle, or the like. Alternatively, the transitional edge may have another shape including a rounded edge, a tapered edge (e.g., another angle besides a 45 degree angle), or the like.

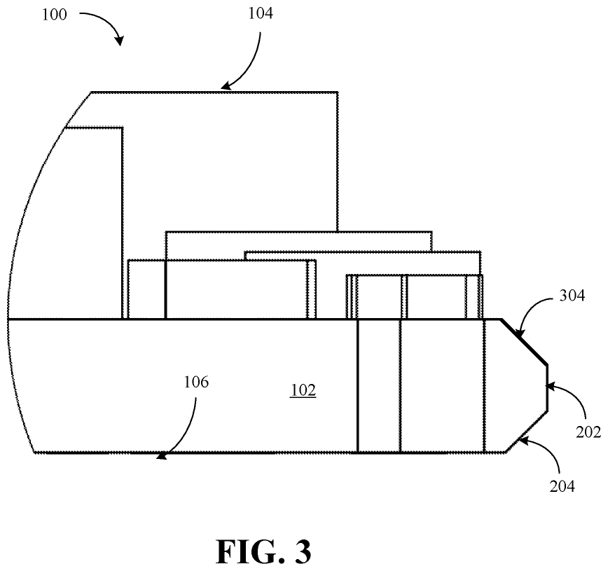

FIG. 3 illustrates an example front view of another edge of the memory device 100 according to an embodiment. As discussed above, the printed circuit board 102 includes a side surface 202 extending perpendicular to the top surface 104 and the back surface 106 and includes a transitional edge 204 extending from the side surface 202 to the back surface 106. As illustrated here, in some implementations, the printed circuit board 102 further includes a second transitional edge 304 extending from the side surface 202 to the top surface 104.

In some examples, the second transitional edge 304 is a chamfered edge. Alternatively, the second transitional edge may have another shape including a rounded edge, a tapered edge (e.g., another angle besides a 45 degree angle), or the like.

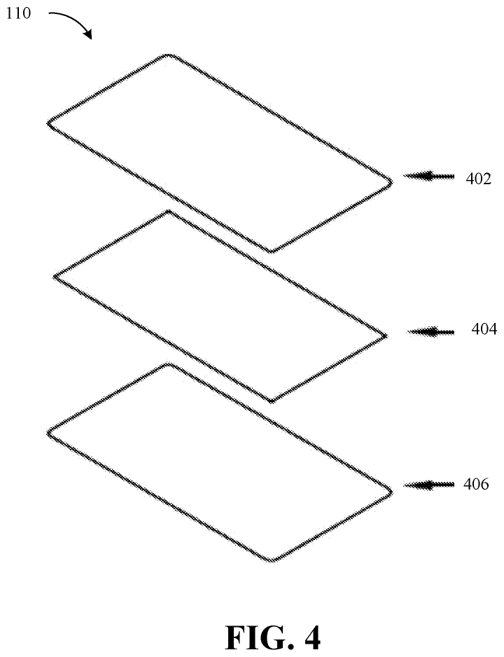

FIG. 4 illustrate an exploded diagram of an example thermal label 110 according to an embodiment. As illustrated, the thermal label 110 includes an embedded thermally conductive layer 404. For example, the embedded thermally conductive layer 404 included graphite, synthetic graphite, copper, the like, and/or combinations thereof.

In some implementations, the thermal label 110 also includes a cover coating layer 402 and an adhesive backing layer 406 that sandwich the embedded thermally conductive layer 404. For example, the cover coating layer 402 may be made from an insulative material, such as a plastic or the like. Additionally, the cover coating layer 402 may be made from a material that is capable of being printed on. The adhesive backing layer 406 may be a double sided adhesive layer for bonding to the embedded thermally conductive layer 404 and the printed circuit board.

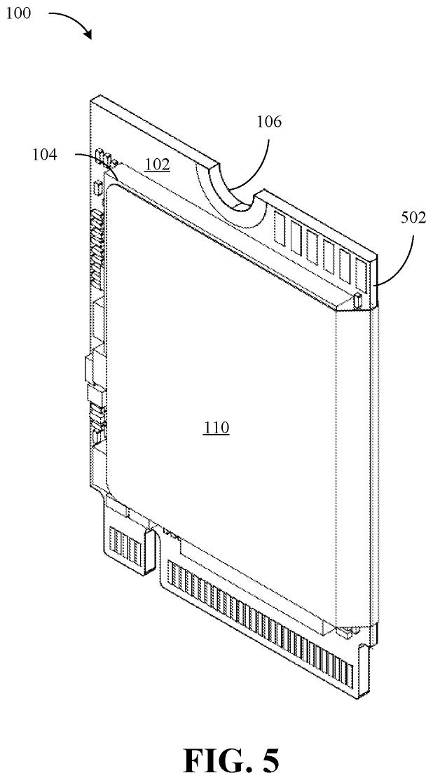

FIG. 5 illustrates a perspective diagram of another example memory device according to an embodiment. As illustrated, during assembly, the thermal label 110 is applied to the printed circuit board 102. For example, the thermal label 110 is adhered to the top 104 of the printed circuit board 102, wrapped around one edge 502 of the printed circuit board 102, and adhered to the back 106 of the printed circuit board 102.

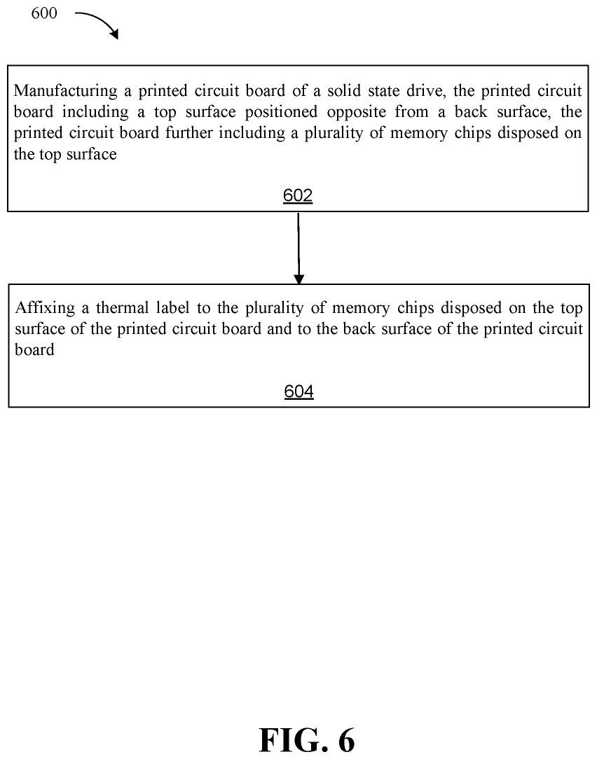

FIG. 6 is a flowchart of an example method 600 of forming a memory device according to an embodiment. The method 600 may generally be implemented to form a memory device, such as, for example, the memory device 100 (e.g., see FIGS. 1-4) having an affixed thermal label 110 (e.g., see FIGS. 1-4), already discussed.

Illustrated processing block 602 provides for manufacturing a printed circuit board of a solid state drive. For example, the printed circuit board including a top surface positioned opposite from a back surface and the printed circuit board further including one or more memory chips disposed on the top surface.

In some examples, a transitional edge is formed. For example, such a transitional edge is formed extending from a side surface of the printed circuit board to the back surface of the printed circuit board, where the side surface extends perpendicular to the top surface and the back surface. In some implementations, the transitional edge is a chamfered edge (e.g., having a 45 degree angle, or the like). Alternatively, the transitional edge may have another shape including a rounded edge, a tapered edge, or the like.

Additionally, in some examples, a second transitional edge is formed. For example, such a second transitional edge is formed extending from the side surface of the printed circuit board to the top surface of the printed circuit board. In some implementations, the second transitional edge is a chamfered edge (e.g., having a 45 degree angle, or the like). Alternatively, the second transitional edge may have another shape including a rounded edge, a tapered edge, or the like.

Illustrated processing block 604 provides for affixing a thermal label. For example, such a thermal label is affixed to the one or more memory chips disposed on the top surface of the printed circuit board and to the back surface of the printed circuit board.

In some examples, the thermal label is affixed to the side surface of the printed circuit board and the transitional edge so as to continuously wrap the thermal label from the top surface of the printed circuit board to the back surface of the printed circuit board.

As used herein the term “continuously wrap” refers to fully contacting whichever surface is described (e.g., the top surface of the printed circuit board, the back surface of the printed circuit board, the side surface of the printed circuit board, the transitional edge, the second transitional edge, the like, and/or combinations thereof) without visible air pockets.

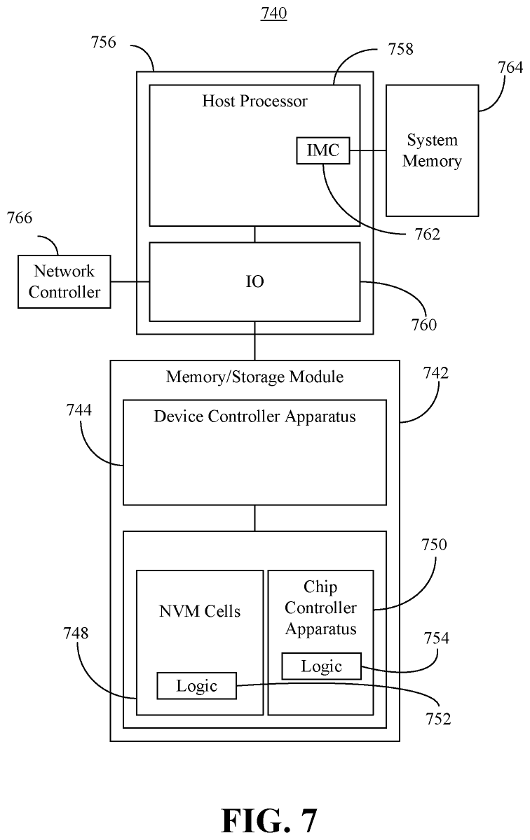

Additional details regarding the various implementations of the method 600 are discussed below with regard to FIG. 7.

Turning now to FIG. 7, a performance-enhanced computing system 740 is shown. In the illustrated example, a solid state drive (SSD) 742 includes a device controller apparatus 744 that is coupled to a NAND 746. The illustrated NAND 746 includes a memory device 748 having a set of multi-level NVM cells and logic 752 (e.g., transistor array and other integrated circuit/IC components coupled to one or more substrates containing silicon, sapphire and/or gallium arsenide), and a chip controller apparatus 750 that includes logic 754. The logic 754 may include one or more of configurable or fixed-functionality hardware.

The illustrated system 740 also includes a system on chip (SoC) 756 having a host processor 758 (e.g., central processing unit/CPU) and an input/output (I/O) module 760. The host processor 758 may include an integrated memory controller 762 (IMC) that communicates with system memory 764 (e.g., RAM dual inline memory modules/DIMMs). The illustrated IO module 760 is coupled to the SSD 742 as well as other system components such as a network controller 766.

In some embodiments, the solid state drive (SSD) 742 implements one or more aspects of the memory device 100 (e.g., see FIGS. 1-4) already discussed. For example, the solid state drive (SSD) 742 is implementable as a structure including having an affixed thermal label 110 (e.g., see FIGS. 1-4) already discussed.

### Additional Notes and Examples

Example 1 includes a solid state drive comprising: a printed circuit board including a top surface positioned opposite from a back surface, the printed circuit board further including one or more memory chips disposed on the top surface; and a thermal label affixed to the one or more memory chips disposed on the top surface of the printed circuit board and affixed to the back surface of the printed circuit board.

Example 2 includes the solid state drive of Example 1, wherein the printed circuit board further comprises: a side surface extending perpendicular to the top surface and the back surface; and a transitional edge extending from the side surface to the back surface.

Example 3 includes the solid state drive of Example 2, wherein the transitional edge is a chamfered edge.

Example 4 includes the solid state drive of any one of Examples 2 to 3, wherein the printed circuit board further comprises:

a second transitional edge extending from the side surface to the top surface.

Example 5 includes the solid state drive of any one of Examples 1 to 4, wherein the solid state drive comprises a form factor that does not exceed thirty millimeters.

Example 6 includes the solid state drive of any one of Examples 1 to 5, further comprising: a housing including a plurality of sides surrounding an interior region, and wherein the printed circuit board is located within the interior region of the housing.

Example 7 includes the solid state drive of any one of Examples 1 to 6, wherein the printed circuit board is sized to accommodate application of the thermal layer to the top surface and the back surface of the printed circuit board while maintaining an overall side thickness of the solid state drive consistent with a first form factor.

Example 8 includes a system comprising: a processor; and a solid state drive coupled to the processor, the solid state drive comprising: a printed circuit board including a top surface positioned opposite from a back surface, the printed circuit board further including one or more memory chips disposed on the top surface; and a thermal label affixed to the one or more memory chips disposed on the top surface of the printed circuit board and affixed to the back surface of the printed circuit board.

Example 9 includes the system of Example 8, wherein the printed circuit board further comprises:

a side surface extending perpendicular to the top surface and the back surface; and a transitional edge extending from the side surface to the back surface.

Example 10 includes the system of Example 9, wherein the transitional edge is a chamfered edge.

Example 11 includes the system of any one of Examples 9 to 10, wherein the printed circuit board further comprises:

a second transitional edge extending from the side surface to the top surface.

Example 12 includes the system of any one of Examples 8 to 11, wherein the solid state drive comprises a form factor that does not exceed thirty millimeters.

Example 13 includes the system of any one of Examples 8 to 12, further comprising: a housing including a plurality of sides surrounding an interior region, and wherein the printed circuit board is located within the interior region of the housing.

Example 14 includes the system of any one of Examples 8 to 13, wherein the printed circuit board is sized to accommodate application of the thermal layer to the top surface and the back surface of the printed circuit board while maintaining an overall side thickness of the solid state drive consistent with a first form factor.

Example 15 includes a method comprising: manufacturing a printed circuit board of a solid state drive, the printed circuit board including a top surface positioned opposite from a back surface, the printed circuit board further including one or more chips disposed on the top surface; and affixing a thermal label to the one or more memory chips disposed on the top surface of the printed circuit board and to the back surface of the printed circuit board.

Example 16 includes the method of Example 15, wherein the method further comprises: forming a transitional edge extending from a side surface of the printed circuit board to the back surface of the printed circuit board, wherein the side surface extends perpendicular to the top surface and the back surface; and affixing the thermal label to the side surface of the printed circuit board and the transitional edge so as to continuously wrap the thermal label from the top surface of the printed circuit board to the back surface of the printed circuit board.

Example 17 includes the method of Example 16, wherein the transitional edge is a chamfered edge.

Example 18 includes the method of any one of Examples 16 to 17, wherein the method further comprises: forming a second transitional edge extending from the side surface to the top surface.

Example 19 includes the method of any one of Examples 15 to 18, wherein the solid state drive comprises a form factor that does not exceed thirty millimeters.

Example 20 includes the method of any one of Examples 15 to 19, wherein the printed circuit board is sized to accommodate application of the thermal layer to the top surface and the back surface of the printed circuit board while maintaining an overall side thickness of the solid state drive consistent with a first form factor.

Example 21 includes an apparatus comprising means for performing the method of any one of Examples 15 to 20.

Example 22 includes a machine-readable storage comprising machine-readable instructions, which when executed, implement a method or realize an apparatus as claimed in any preceding claim.

Technology described herein therefore provides the capability for affixing a thermal label to a solid state drive. Advantageously, such techniques provide for the thermal label to move the heat away from the hot components on the top of the SSD to other areas of the SSD (e.g., to the back of the SSD) that are typically cooler. This typically increases the time for the drive components to reach temperatures that trigger throttling, which advantageously results in improved throughput performance.

Embodiments are applicable for use with all types of semiconductor integrated circuit (“IC”) chips. Examples of these IC chips include but are not limited to processors, controllers, chipset components, programmable logic arrays (PLAs), memory chips, network chips, systems on chip (SoCs), SSD/NAND controller ASICs, and the like. In addition, in some of the drawings, signal conductor lines are represented with lines. Some may be different, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

Unless specifically stated otherwise, it may be appreciated that terms such as “processing,” “computing,” “calculating,” “determining,” or the like, refer to the action and/or processes of a computer or computing system, or similar electronic computing device, that manipulates and/or transforms data represented as physical quantities (e.g., electronic) within the computing system's registers and/or memories into other data similarly represented as physical quantities within the computing system's memories, registers or other such information storage, transmission or display devices. The embodiments are not limited in this context.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the platform within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical, or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A; B; C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A solid state drive comprising:
a printed circuit board including a top surface positioned opposite from a back surface, the printed circuit board further including one or more memory chips disposed on the top surface; and
a thermal label affixed to the one or more memory chips disposed on the top surface of the printed circuit board and affixed to the back surface of the printed circuit board.

2. The solid state drive of claim 1, wherein the printed circuit board further comprises:
a side surface extending perpendicular to the top surface and the back surface; and
a transitional edge extending from the side surface to the back surface.

3. The solid state drive of claim 2, wherein the transitional edge is a chamfered edge.

4. The solid state drive of claim 3, wherein the printed circuit board further comprises:
a second transitional edge extending from the side surface to the top surface.

5. The solid state drive of claim 1, wherein the solid state drive comprises a form factor that does not exceed thirty millimeters.

6. The solid state drive of claim 1, further comprising:
a housing including a plurality of sides surrounding an interior region, and wherein the printed circuit board is located within the interior region of the housing.

7. The solid state drive of claim 1, wherein the printed circuit board is sized to accommodate application of the thermal layer to the top surface and the back surface of the printed circuit board while maintaining an overall side thickness of the solid state drive consistent with a first form factor.

8. A system comprising:
a processor; and
a solid state drive coupled to the processor, the solid state drive comprising:
a printed circuit board including a top surface positioned opposite from a back surface, the printed circuit board further including one or more memory chips disposed on the top surface; and
a thermal label affixed to the one or more memory chips disposed on the top surface of the printed circuit board and affixed to the back surface of the printed circuit board.

9. The system of claim 8, wherein the printed circuit board further comprises:
a side surface extending perpendicular to the top surface and the back surface; and
a transitional edge extending from the side surface to the back surface.

10. The system of claim 9, wherein the transitional edge is a chamfered edge.

11. The system of claim 10, wherein the printed circuit board further comprises:
a second transitional edge extending from the side surface to the top surface.

12. The system of claim 8, wherein the solid state drive comprises a form factor that does not exceed thirty millimeters.

13. The system of claim 8, further comprising:
a housing including a plurality of sides surrounding an interior region, and wherein the printed circuit board is located within the interior region of the housing.

14. The system of claim 8, wherein the printed circuit board is sized to accommodate application of the thermal layer to the top surface and the back surface of the printed circuit board while maintaining an overall side thickness of the solid state drive consistent with a first form factor.

15. A method comprising:
manufacturing a printed circuit board of a solid state drive, the printed circuit board including a top surface positioned opposite from a back surface, the printed circuit board further including one or more memory chips disposed on the top surface; and
affixing a thermal label to the one or more memory chips disposed on the top surface of the printed circuit board and to the back surface of the printed circuit board.

16. The method of claim 15, wherein the method further comprises:
forming a transitional edge extending from a side surface of the printed circuit board to the back surface of the printed circuit board, wherein the side surface extends perpendicular to the top surface and the back surface; and
affixing the thermal label to the side surface of the printed circuit board and the transitional edge so as to continuously wrap the thermal label from the top surface of the printed circuit board to the back surface of the printed circuit board.

17. The method of claim 16, wherein the transitional edge is a chamfered edge.

18. The method of claim 17, wherein the method further comprises:
forming a second transitional edge extending from the side surface to the top surface.

19. The method of claim 15, wherein the solid state drive comprises a form factor that does not exceed thirty millimeters.

20. The method of claim 15, wherein the printed circuit board is sized to accommodate application of the thermal layer to the top surface and the back surface of the printed circuit board while maintaining an overall side thickness of the solid state drive consistent with a first form factor.
